(19) United States
(12) Patent Application Publication
(10) Pub. No.: US 2011/0121335 A1
(43) Pub. Date: May 26, 2011

(54) LIGHT EMITTING MODULE AND MANUFACTURING METHOD THEREOF

(75) Inventors: Sadamichi Takakusaki, Ota-shi (JP); Tatsuya Motoike, Tottori-shi (JP); Akihisa Matsumoto, Tottori-shi (JP)

(73) Assignees: SANYO Electric Co., Inc., Moriguchi-shi (JP); SANYO Semiconductor Co., Ltd., Gunma (JP); SANYO Consumer Electronics Co., Ltd., Tottori-shi (JP)

(21) Appl. No.: 12/674,564

(22) PCT Filed: Aug. 28, 2008
(86) PCT No.: PCT/JP2008/066130

§ 371 Date: Feb. 22, 2010

(30) Foreign Application Priority Data
Aug. 31, 2007 (JP) 2007-225567

(51) Int. Cl. H01L 33/60; H01L 33/48

(52) U.S. Cl. 257/98; 257/99; 438/26; 438/27; 257/E33.057; 257/E33.072

(57) ABSTRACT

Provided are a light emitting module and a manufacturing method thereof, the light emitting module having improved heat radiation properties and improved adhesion between a sealing resin for sealing a light emitting element and other members. A light emitting module 10 includes: a metal substrate 12; a concave part 18 provided by partially denting an upper surface of the metal substrate 12; a light emitting element 20 accommodated in the concave part 18; and a sealing resin 32 covering the light emitting element 20. A convex part 11 is further provided on the upper surface of the metal substrate 40 in a region thereof surrounding the concave part 18. The sealing resin 32 is allowed to adhere to the convex part 11, thereby improving adhesion strength between the sealing resin 32 and the metal substrate 12.

### TECHNICAL FIELD

The present invention relates to a light emitting module and a manufacturing method thereof, and particularly to a light emitting module having a high-intensity light emitting element mounted thereon, and a manufacturing method thereof.

### BACKGROUND ART

A semiconductor light emitting element typified by an LED (light emitting diode) has a long life and high visibility and thus has been used for a traffic light, a lamp of an automobile, and the like. Meanwhile, an LED is also being used for lighting equipment.

When an LED is used for lighting equipment, a number of LEDs are mounted in one set of lighting equipment since only one LED does not give enough brightness. However, LEDs release a large amount of heat when emitting light. Therefore, when LEDs are mounted on a mounting substrate made of a resin material with poor heat radiation properties or when individual LEDs are separately packaged with resin, the heat released from the LEDs is not effectively released to the outside. This leads to a problem that the performance of LEDs is quickly degraded.

Japanese Patent Application Publication No. 2006-100753 discloses a technique of mounting LEDs on an upper surface of a metal substrate made of aluminum for effectively releasing heat generated by the LEDs to the outside. Particularly, with reference to FIG. 2 in Japanese Patent Application Publication No. 2006-100753, an upper surface of a metal substrate 11 is covered with an insulating resin 13 and a light emitting element 15 (LED) is mounted on an upper surface of a conductive pattern 14 formed on an upper surface of the insulating resin 13. With this configuration, heat generated by the light emitting element 16 is released to the outside through the conductive pattern 14, the insulating resin 13 and the metal substrate 11.

### DISCLOSURE OF THE INVENTION

In the technique described in Japanese Patent Application Publication No. 2006-100753, however, the insulating resin 13 is interposed between the metal substrate 11 and the conductive pattern 14 having the light emitting element 15, which is an LED, fixed thereon. Here, the insulating resin 13 is extensively filled with a filler to improve the heat radiation properties, but thermal resistance thereof is higher than that of metal. Therefore, when light is generated by using, as the light emitting element 16, a high-intensity LED through which a large current of, for example, 200 mA or more passes, the configuration described in Japanese Patent Application Publication No. 2006-100753 has a possibility that heat radiation is insufficient.

Furthermore, since adhesion between the sealing resin for sealing the light emitting element 15 and the other member (e.g., substrate) is insufficient, there is a risk that the sealing resin peels off from the substrate due to a thermal stress attributable to a temperature change in a use situation.

The present invention has been made in consideration of the foregoing problems. It is a main object of the present invention to provide a light emitting module having improved heat radiation properties and improved adhesion between a sealing resin for sealing a light emitting element and other members, and also to provide a manufacturing method thereof.

A light emitting module of the present invention includes: a metal substrate having a first principal surface and a second principal surface and made of a metal; an insulating layer covering the first principal surface of the metal substrate; a conductive pattern formed on a surface of the insulating layer; an opening provided by partially removing the insulating layer; a concave part provided by denting the metal substrate exposed from the opening; and a light emitting element accommodated in the concave part and electrically connected to the conductive pattern.

A method for manufacturing a light emitting module of the present invention includes the steps of: forming a conductive pattern on a surface of an insulating layer covering a first principal surface of a metal substrate; providing an opening by partially removing the insulating layer, so that the first principal surface of the metal substrate is partially exposed from the opening; forming a concave part by denting the metal substrate exposed from the opening; accommodating a light emitting element in the concave part; and electrically connecting the light emitting element to the conductive pattern.

A light emitting module of the present invention includes: a substrate having a first principal surface and a second principal surface; a conductive pattern formed on the first principal surface of the substrate; a concave part provided by denting the substrate from the first principal surface; a light emitting element accommodated in the concave part and electrically connected to the conductive pattern; a convex part formed by raising the first principal surface of the substrate in a region thereof surrounding the concave part; and a sealing resin filled in the concave part so as to cover the light emitting element and adhering to the convex part.

A method for manufacturing a light emitting module of the present invention includes the steps of: forming a conductive pattern on a first principal surface of a substrate; pressing the substrate so that the substrate is dent from the first principal surface and thus a concave part is provided and so that the first principal surface of the substrate is raised in a region thereof surrounding the concave part and thus a convex part is provided; accommodating a light emitting element in the concave part and electrically connecting the light emitting element to the conductive pattern; and forming a sealing resin so that the sealing resin is filled in the concave part so as to cover the light emitting element and adheres to the convex part.

According to the present invention, the opening is provided by partially removing the insulating layer covering the metal substrate, the principal surface of the metal substrate exposed from the opening is formed into a concave part, and the light emitting element is fixed to the concave part. Therefore, since the light emitting element is fixed directly to the concave part in the metal substrate, heat generated by the light emitting element is efficiently released to the outside through the metal substrate.

Furthermore, the side surface of the concave part is formed as an inclined surface and is thus utilized as a reflector. Thus, the number of components required can be reduced and cost of the light emitting module can be reduced.

According to the present invention, the convex part is provided by raising the surface of the substrate so as to surround the concave part which accommodates the light emitting element, and the sealing resin filled in the concave part for sealing the light emitting element is brought into contact with the convex part. This configuration allows the sealing resin to adhere to the convex part provided on the surface of the substrate, and thus prevents the sealing resin from peeling off from the substrate.

Furthermore, in the present invention, the light emitting element is accommodated in the concave part formed by denting the substrate. Therefore, the heat generated by the light emitting element can be efficiently released to the outside through the substrate made of metal, for example.

In a manufacturing process, the concave part and the convex part therearound can be simultaneously formed by pressing the upper surface of the substrate with a mold. Thus, the convex part can be formed while suppressing an increase in the number of steps.

### BRIEF DESCRIPTION OF THE DRAWINGS

FIG. 1 shows views each illustrating configuration of a light emitting module according to the present invention. FIG. 1A is a perspective view and FIGS. 1B and 1C are cross-sectional views.

FIG. 2 shows views each illustrating a method for manufacturing the light emitting module according to the present invention. FIGS. 2A and 2B are cross-sectional views and FIG. 2C is a plan view.

FIG. 3 shows views each illustrating the method for manufacturing the light emitting module according to the present invention. FIGS. 3A to 3C are cross-sectional views and FIG. 3D is a plan view.

FIG. 4 shows views each illustrating the method for manufacturing the light emitting module according to the present invention. FIGS. 4A to 4D are cross-sectional views.

FIG. 5 shows views each illustrating the method for manufacturing the light emitting module according to the present invention. FIG. 5A is a cross-sectional view and FIG. 5B is a plan view.

FIG. 6 shows views each illustrating the method for manufacturing the light emitting module according to the present invention. FIG. 6A is a cross-sectional view and FIG. 6B is a plan view.

FIG. 7 shows views each illustrating the method for manufacturing the light emitting module according to the present invention. FIGS. 7A and 7B are cross-sectional views and FIG. 7C is a plan view.

FIG. 8 shows views each illustrating the method for manufacturing the light emitting module according to the present invention. FIGS. 8A and 8B are cross-sectional views and FIG. 8C is a plan view.

FIG. 9 shows views each illustrating the method for manufacturing the light emitting module according to the present invention. FIGS. 9A and 9B are cross-sectional views and FIG. 9C is a plan view.

FIG. 10 shows views each illustrating the method for manufacturing the light emitting module according to the present invention. FIG. 10A is a cross-sectional view and FIG. 10B is a plan view.

### BEST MODE FOR CARRYING OUT THE INVENTION

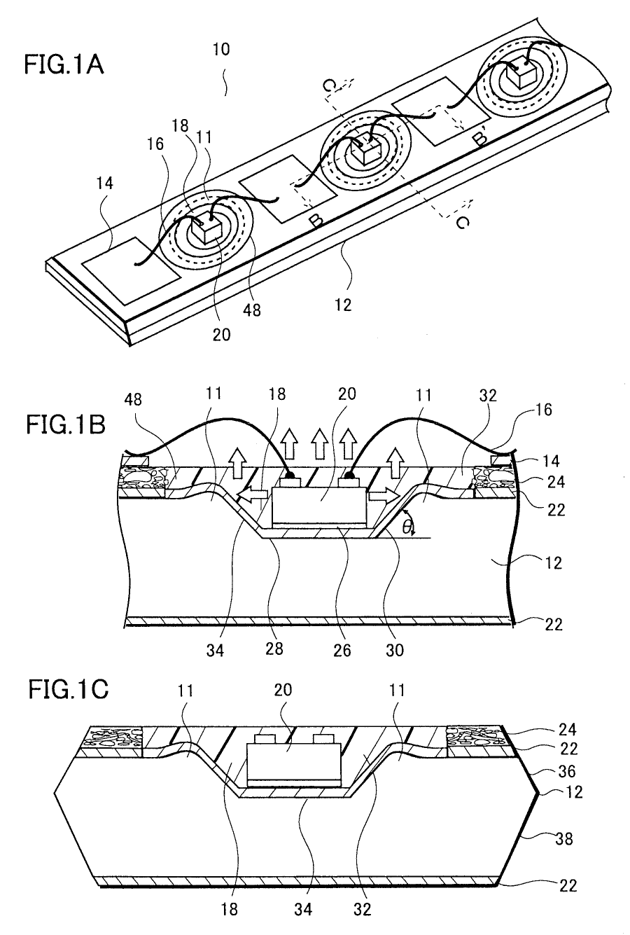

With reference to FIG. 1, a configuration of a light emitting module 10 according to the present invention will be described. FIG. 1A is a perspective view of the light emitting module 10, FIG. 1B is a cross-sectional view along the line B-B′ in FIG. 1A, and FIG. 1C is a cross-sectional view along the line C-C′ in FIG. 1A.

With reference to FIGS. 1A to 1C, the light emitting module 10 mainly includes: a metal substrate 12; a conductive pattern 14 formed on an upper surface of the metal substrate 12; concave parts 18 each provided by partially denting the upper surface of the metal substrate 12; convex parts 11 each formed by raising the upper surface of the metal substrate 12 in a peripheral portion of the corresponding concave part 18; light emitting elements 20 each accommodated in the corresponding concave part 18; and sealing resin 32 covering the light emitting elements 20.

With reference to FIG. 1A, the light emitting module 10 has plural light emitting elements 20 mounted on the upper surface of a single plate-shaped metal substrate 12. These light emitting elements 20 are connected together in series through the conductive pattern 14 and thin metal wires 16. By supplying a direct current to the light emitting module 10 thus configured, light of a predetermined color is emitted from the light emitting elements 20. Thus, the light emitting module 10 functions, for example, as lighting equipment like a fluorescent light.

The metal substrate 12 is a substrate made of a metal such as copper (Cu) or aluminum (Al) and has, for example, a thickness of not smaller than 0.5 mm but not larger than 2.0 mm, a width of not smaller than 2 mm but not larger than 20 mm and a length of not smaller than 5 cm but not larger than 50 cm. When the metal substrate 12 is made of aluminum, the upper and lower surfaces of the metal substrate 12 are covered with an oxide film 22 (alumite film: Al₂O₃) obtained by anodizing aluminum. With reference to FIG. 1B, a thickness of the oxide film 22 covering the upper and lower surfaces of the metal substrate 12 is, for example, not smaller than 1 μm but not larger than 10 μm. Moreover, the metal substrate 12 has a very long and narrow shape since the plural light emitting elements 20 are arranged in a row to secure a predetermined amount of light. On both ends of the metal substrate 12 in its longitudinal direction, external connection terminals to be connected to an outside power source are formed, respectively. These terminals may be plug-in connectors or may be ones obtained by soldering wiring to the conductive pattern 14.

With reference to FIG. 1C, each of side surfaces of the metal substrate 12 has a shape protruding outward. To be more specific, each of the side surfaces of the metal substrate 12 includes: a first inclined portion 36 inclined outward continuously from the upper surface of the metal substrate 12; and a second inclined portion 38 inclined outward continuously from the lower surface of the metal substrate 12. This configuration can increase an area of each of the side surfaces of the metal substrate 12 compared with that in a flat shape. As a result, an amount of heat to be released to the outside from each of the side surfaces of the metal substrate 12 is increased. Particularly, the side surfaces of the metal substrate 12 are not covered with the oxide film 22 having high thermal resistance, and are surfaces where a metal material having excellent heat radiation properties is exposed. Thus, the above configuration improves heat radiation properties of the entire module.

With reference to FIG. 1B, the upper surface of the metal substrate 12 is covered with an insulating layer 24 made of resin mixed with a filler such as Al₂O₃. A thickness of the insulating layer 24 is, for example, approximately 50 μm. The insulating layer 24 has a function to insulate the metal substrate 12 and the conductive pattern 14 from each other. Moreover, a large amount of filler is mixed in the insulating layer 24, which allows a thermal expansion coefficient of the insulating layer 24 to be approximated to that of the metal substrate 12, and also allows a reduction in thermal resistance of the insulating layer 24. For example, the insulating layer 24 contains not smaller than 70 volume % but not larger than 80 volume % of filler. In addition, an average particle size of the filler contained is, for example, approximately 4 μm.

With reference to FIGS. 1A and 1B, the conductive pattern 14 is formed on an upper surface of the insulating layer 24 and functions as a part of a path for allowing conduction between the light emitting elements 20. The conductive pattern 14 is formed by etching a conductive foil made of copper or the like and provided on the upper surface of the insulating layer 24. Furthermore, the conductive pattern 14 provided on the both ends of the metal substrate 12 may also function as the external connection terminals which contribute to connections to the outside.

Each light emitting element 20 has two electrodes (anode electrode and cathode electrode) on its upper surface and emits light of a predetermined color. The light emitting element 20 is configured by laminating an N type semiconductor layer and a P type semiconductor layer on a semiconductor substrate made of GaAs, GaN or the like. A specific size of the light emitting element 20 is, for example, approximately 0.3 mm to 1.0 mm in length, 0.3 mm to 1.0 mm in width, and 0.1 mm in thickness. Furthermore, a thickness of the light emitting element 20 varies depending on the color of light to be emitted. For example, a thickness of the light emitting element 20 which emits red light is approximately 100 to 300 μm. A thickness of the light emitting element 20 which emits green light is approximately 100 μm. A thickness of the light emitting element 20 which emits blue light is approximately 100 μm When a voltage is applied to the light emitting element 20, light is emitted from its upper surface and upper portions of its side surfaces. Here, the configuration of the light emitting module 10 according to the present invention has excellent heat radiation properties and is thus particularly useful for the light emitting element 20 (power LED) through which a current of 100 mA or more passes, for example.

In FIG. 1B, light emitted from the light emitting element 20 is indicated by white arrows. The light emitted from the upper surface of the light emitting element 20 travels upward without interference. Meanwhile, light emitted laterally from the side surfaces of the light emitting element 20 is reflected upward by a side surface 30 of the concave part 18. Furthermore, since the light emitting element 20 is covered with the sealing resin 32 having a fluorescent material mixed therein, the light generated by the light emitting element 20 transmits through the sealing resin 32 and is emitted to the outside.

Furthermore, the two electrodes (anode electrode and cathode electrode) are disposed on the upper surface of the light emitting element 20. These electrodes are connected to the conductive pattern 14 via the thin metal wires 16, respectively. Here, connecting portions between the electrodes of the light emitting element 20 and the thin metal wires 16 are covered with the sealing resin 32.

With reference to FIG. 1B, a description will be given of a shape of a portion where the light emitting element 20 that is an LED is mounted. First, an opening 48 is provided by partially circularly removing the insulating layer 24. Thereafter, by denting the upper surface of the metal substrate 12 exposed from the inside of the opening 48, the concave part 18 is formed. The light emitting element 20 is fixed to a bottom surface 28 of this concave part 18. Furthermore, the light emitting element 20 is covered with the sealing resin 32 filled in the concave part 18 and the opening 48. In addition, the convex part 11 is provided by raising the upper surface of the metal substrate 12 in the peripheral portion of the concave part 18. The sealing resin 32 is also allowed to adhere to this convex part 11.

The concave part 18 is formed in the metal substrate 12 by denting the upper surface thereof, and the bottom surface 28 has a circular shape. Moreover, the side surface of the concave part 18 functions as a reflector for reflecting light upward, the light being emitted laterally from the side surfaces of the light emitting element 20. The outer side of the side surface 30 and the bottom surface 28 form an angle θ of, for example, not smaller than 40° but not larger than 60°. The depth of the concave part 18 may be greater or smaller than the thickness of the light emitting element 20. For example, when the thickness of the concave part 18 is set to be greater than a length equivalent to the thickness obtained by adding the thickness of the light emitting element 20 and that of a bonding material 26, the light emitting element 20 can be accommodated in the concave part 18, and the upper surface of the light emitting element 20 can be positioned lower than the upper surface of the metal substrate 12.

The bottom surface 28 and side surface 30 of the concave part 18 as well as the upper surface of the metal substrate 12 near the concave part 18 are covered with a cover layer 34. As a material of the cover layer 34, gold (Au) or silver (Ag) formed by a plating process is used. In addition, when a material (for example, gold or silver) that has higher reflectance than the material of the metal substrate 12 is used as the material of the cover layer 34, the light emitted laterally from the light emitting element 20 can be reflected upward more efficiently. Moreover, the cover layer 34 has a function to prevent an inner wall of the concave part 18, on which the metal is exposed, from being oxidized in a manufacturing process of the light emitting module 10.

On the bottom surface 28 of the concave part, the oxide film 22 that covers the surface of the metal substrate 12 is removed. The oxide film 22 has higher thermal resistance than that of the metal which forms the metal substrate 12. Thus, by removing the oxide film 22 from the bottom surface of the concave part 18 on which the light emitting element 20 is mounted, the thermal resistance of the entire metal substrate 12 is reduced.

With reference to FIGS. 1A and 1B, the convex part 11 is provided by causing the upper surface of the metal substrate 12 to protrude upward so as to surround the concave part 18. The convex part 11 is continuous with the side surface 30 of the concave part 18, and a surface thereof protrudes upward in a gently curved shape. A height of the convex part 11 protruding upward from the upper surface of the metal substrate 12 is, for example, not smaller than 10 μm but not larger than 50 μm. Here, the convex part 11 may be provided in a continuous circular shape so as to surround the concave part 18, or may be provided discretely (in a discontinuous shape).

The sealing resin 32 is filled in the concave part 18 and the opening 48 to seal the light emitting element 20. The sealing resin 32 is formed by mixing a fluorescent material into a silicone resin with excellent heat resistant properties. For example, when blue light is emitted from the light emitting element 20 and a yellow fluorescent material is mixed in the sealing resin 32, the light transmitted through the sealing resin 32 turns white. In this manner, the light emitting module 10 can be utilized as lighting equipment that emits white light. Moreover, in the present invention, the sealing resin 32 also is in contact with the convex part 11 provided around the concave part 18. Thus, the sealing resin 32 firmly adheres to the convex part 11 and is thereby prevented from peeling off from the metal substrate 12.

Furthermore, the convex part 11 provided so as to surround the concave part 18 as described above suppresses irradiation of the upper surface of the metal substrate 12 with the light generated by the light emitting element 20. Therefore, discoloration of the insulating layer 24 covering the upper surface of the metal substrate 12 is prevented. Furthermore, such an effect achieved by the convex part 11 eliminates the need for any special base material for preventing discoloration or deterioration of the insulating layer 24. Thus, cost can be reduced accordingly.

Here, the convex part 11 is not necessarily required. For example, the upper surface of the metal substrate 12 in the peripheral portion of the concave part 18 may be set to be flat instead of providing the convex part 11.

Moreover, a side surface of the insulating layer 24 facing the opening 48 is a rough surface on which the filler is exposed. This leads to an advantage that an anchoring effect achieved between the rough side surface of the insulating layer 24 and the sealing resin 32 can prevent peeling off of the sealing resin 32.

The bonding material 26 has a function to bond a lower surface of the light emitting element 20 and the concave part 18 together. Since the light emitting element 20 has no electrode on the lower surface thereof, the bonding material 26 may be formed of an insulating resin or may be formed of metal such as solder to improve the heat radiation properties. Meanwhile, since the bottom surface of the concave part 18 is covered with a plating film (cover layer 34) made of silver or the like with excellent solder wettability, solder can be readily employed as the bonding material 26.

In the present invention, the convex part 11 is formed by partially raising the upper surface of the metal substrate 12 in the peripheral portion of the concave part 18, and the sealing resin 32 is allowed to adhere to the convex part 11. To be more specific, since the side surface 30 of the concave part 18 is an inclined surface in the present invention, adhesion strength between the metal substrate 12 and the sealing resin 32 formed so as to be filled in the concave part 18 is not that strong. For this reason, in the present invention, the convex part 11 is formed by causing the metal substrate 12 in the region thereof surrounding the concave part 18 to partially protrude upward, and the sealing resin 32 is allowed to adhere to the convex part 11. In this way, first, an area of contact between the surface of the metal substrate 12 and the sealing resin 32 is increased and thus the adhesion strength therebetween is increased. Furthermore, an anchoring effect achieved between the convex part 11 and the sealing resin 32 increases the adhesion strength between the sealing resin 32 and the metal substrate 12. Thus, the peeling off of the sealing resin 32 from the metal substrate 12 due to a temperature change in a use situation can be prevented.

The present invention has an advantage that the heat generated by the light emitting element 20 can be very efficiently released to the outside by mounting the bare light emitting element 20 on the upper surface of the metal substrate 12. To be more specific, in the conventional example described above, a light emitting element is mounted on a conductive pattern formed on an upper surface of an insulating layer, and accordingly the insulating layer inhibits heat conduction. This makes it difficult to efficiently release the heat from the light emitting element 20 to the outside. On the other hand, in the present invention, the insulating layer 24 and the oxide film 22 are removed to form the opening 48 in the region where the light emitting element 20 is to be mounted, and the light emitting element 20 is fixed to the surface of the metal substrate 12 exposed from the opening 48. In this way, the heat generated by the light emitting element 20 is immediately transferred to the metal substrate 12 and released to the outside. Thus, an increase in temperature of the light emitting element 20 is suppressed. Moreover, by the suppression of the increase in temperature, the deterioration of the sealing resin 32 is also suppressed.

Furthermore, in the present invention, the side surface of the concave part 18 provided in the upper surface of the metal substrate 12 can be utilized as a reflector. Specifically, with reference to FIG. 1B, the side surface of the concave part 18 is an inclined surface formed such that the width of the concave part gradually increases toward the upper surface of the metal substrate 12. This side surface 30 thus reflects light emitted laterally from the side surface of the light emitting element 20 and causes the light to travel upward. In other words, the side surface 30 of the concave part 18 accommodating the light emitting element 20 also functions as a reflector. This eliminates the need to separately prepare a reflector as in a case of a general light emitting module, thereby reducing the number of components and enabling cost reduction. In addition, by covering the side surface 30 of the concave part with the material having high reflectance as described above, the function of the side surface 30 as a reflector can be enhanced.

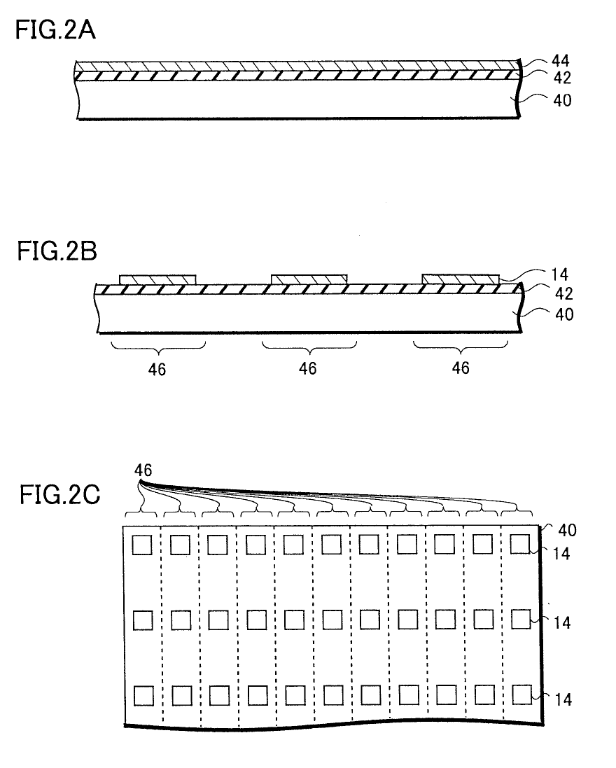

Next, with reference to FIGS. 2 to 10, a description will be given of a method for manufacturing the light emitting module 10 having the above configuration.

First Step:

With reference to FIG. 2, first, a substrate 40 that is a base material of a light emitting module 10 is prepared, and then a conductive pattern is formed thereon.

With reference to FIG. 2A, first, the substrate 40 is made of metal containing, for example, copper or aluminum as a main material. The substrate 40 has a thickness of not smaller than 0.5 mm but not larger than 2.0 mm. A planar size of the substrate 40 is, for example, approximately 1 m×1 m, and a single substrate 40 produces multiple light emitting modules. When the substrate 40 is made of aluminum, upper and lower surfaces of the substrate 40 are covered with an anodized film as described above.

The upper surface of the substrate 40 is entirely covered with an insulating layer 42 having a thickness of approximately 50 μm. The composition of the insulating layer 42 is the same as that of the insulating layer 24 described above. The insulating layer 42 is made of a resin material extensively filled with filler. Moreover, on the entire upper surface of the insulating layer 42, a conductive foil 44 made of copper and having a thickness of approximately 50 μm is formed.

With reference to FIG. 2B, the conductive foil 44 is then patterned by performing selective wet etching to thereby form conductive patterns 14. Units 46 provided to the substrate 40 each have the same shape of the conductive pattern 14. Here, each unit 46 is a portion that forms a single light emitting module.

FIG. 2C shows a plan view of the substrate 40 after the completion of this step. Here, a boundary between each pair of adjacent units 46 is indicated by a dotted line. The unit 46 is, for example, approximately 30 cm in length and 0.5 cm in width, and has a considerably thin and narrow shape.

Second Step:

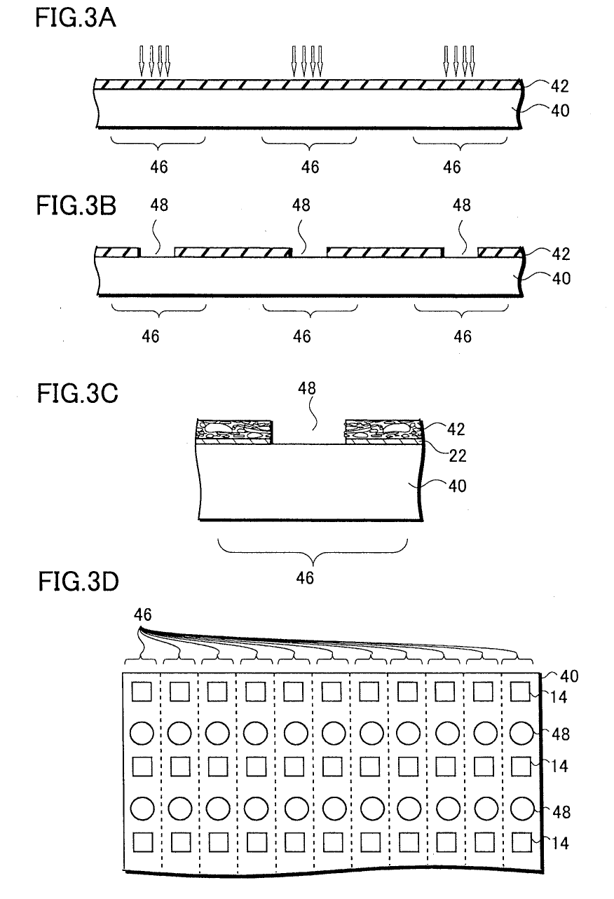

With reference to FIG. 3, openings 48 are provided to each unit 46 in the substrate 40 by partially removing the insulating layer.

With reference to FIG. 3A, the insulating layer 42 is irradiated from above with laser light. Here, the laser light used for the irradiation is indicated by arrows. The laser irradiation is performed on the insulating layer 42 corresponding to the portions (here, circular portions) where light emitting elements are to be mounted. A laser to be used here is a carbon dioxide laser or a YAG laser.

With reference to FIGS. 3B and 3C, the insulating layer 42 is partially circularly removed by the laser irradiation described above and the openings 48 are formed. Particularly, with reference to FIG. 3C, not only the insulating layer 42 but also the oxide film 22 that covers the upper surface of the substrate 40 is removed. As a result, the metal material (e.g., aluminum) that forms the substrate 40 is exposed from bottom surfaces of the openings 48.

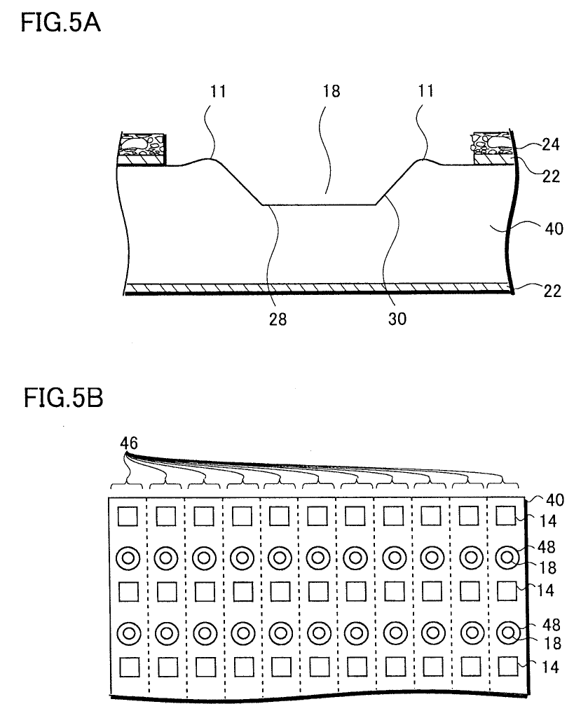

With reference to FIG. 3D, the openings 48 described above have a circular shape and provided so as to correspond to the regions where the light emitting elements in each unit 46 are to be fixed. Here, a planar size of each opening 48 is set larger than that of a corresponding concave part 18 or convex part 11 (see FIG. 5) to be formed inside the opening 48 in a subsequent step. Specifically, a peripheral edge of the opening 48 is separated from a peripheral edge of the concave part 18 or the convex part 11. Thus, the insulating layer, which is fragile, can be prevented from being broken by the impact resulting from pressing performed to form the concave part 18 and the convex part 11.

Third Step:

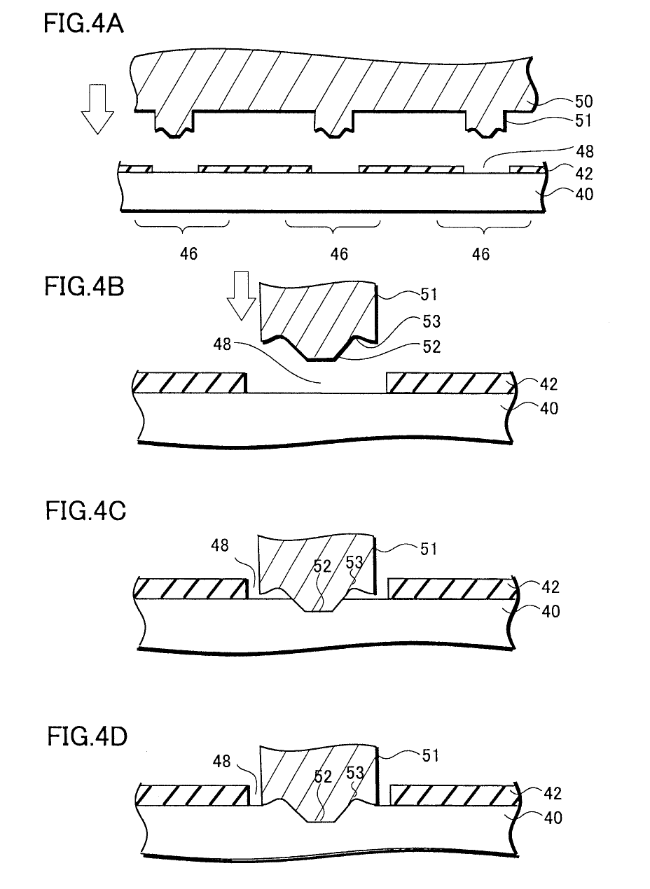

With reference to FIGS. 4 and 5, next, a concave part 18 and a convex part 11 are formed in the upper surface of the substrate 40 exposed from each opening 48. In this step, the concave part 18 and the convex part 11 can be simultaneously formed by press working.

With reference to FIG. 4A, a mold for pressing is first prepared. In a mold 50, multiple contact portions 51 protruding downward are provided in the regions corresponding to the openings 48 on the substrate 40. In this step, as the mold 50 is pressed downward, the upper surface of the substrate 40 exposed from the openings 48 is pressed by the contact portions of the mold 50, and thereby the concave parts 18 and the convex parts 11 are formed.

With reference to FIG. 4B, each of the contact portions 51 has a schematically cylindrical shape, and has a convex portion 52 and a concave portion 53 formed in its lower surface. Here, the convex portion 52 has a shape corresponding to the concave part 18 to be formed, and the shape thereof is a conical shape having its tip cut off. The concave portion 53 has a shape corresponding to the convex part 11 to be formed, and is a region obtained by denting a periphery of the convex portion 52 on the lower surface of the contact portion 51. By providing the concave portion 53 in the lower surface of the contact portion 51, the shape and position of the convex part 11 to be formed in this step can be accurately controlled.

With reference to FIG. 4C, next, the upper surface of the substrate 40 exposed from the opening 48 is pressed by the convex portion 52 provided at the lower end of the contact portion 51. Thus, a concave part having a shape corresponding to the convex portion 52 is formed in the upper surface of the substrate 40. Thereafter, with reference to FIG. 4D, as the contact portion 51 of the mold is further moved downward, the metal material of the substrate 40 is pushed upward in response to the pressing by the convex portion 52 and is moved to the concave portion 53 of the contact portion. Subsequently, the pushed part of the metal material is held by a lower surface of the concave portion 53 of the contact portion 51 and thus a convex part having a predetermined shape is formed.

FIG. 5A shows the shape of the concave part 18 thus formed. By the press working described above, the concave part 18 is formed, which has a circular bottom surface 28 and an inclined side surface 30. In addition, the convex part 11 having a predetermined shape is formed on the upper surface of the substrate 40 around the concave part 18. Moreover, the concave part 18 thus formed may have such a depth that the light emitting element to be mounted in a subsequent step is completely accommodated therein, or that the light emitting element is partially accommodated therein. Specifically, the depth of the concave part 18 is, for example, not smaller than 100 μm but not larger than 300 μm. Furthermore, although the convex part 11 has a smooth cross-sectional shape here, the convex part 11 may be formed into a different shape by changing the shape of the concave portion 53 of the contact portion 51 described above. For example, minute asperities may be formed on the surface of the convex part 11 to improve adhesion with the resin material.

With reference to FIG. 5B, by the above method, the concave parts 18 and the convex parts 11 are formed in the regions of each unit 46 where the light emitting elements are to be mounted.

Fourth Step:

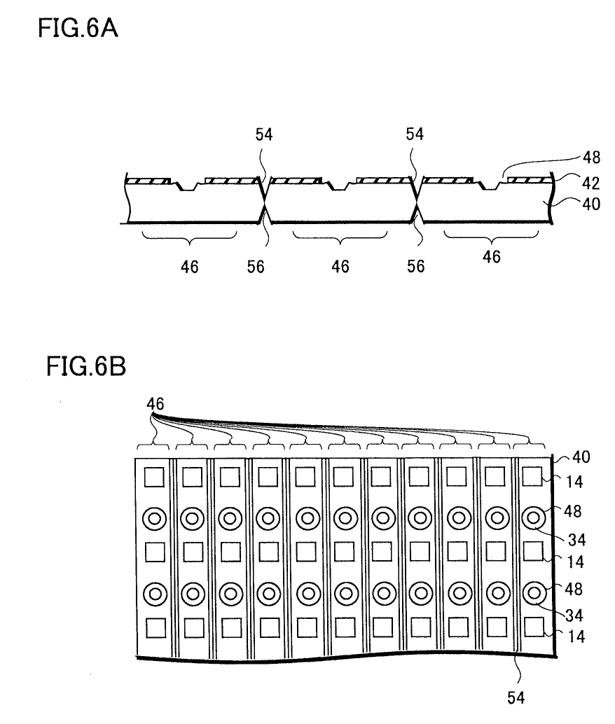

With reference to FIGS. 6A and 6B, next, an isolation groove is provided between each pair of the adjacent units 46. With reference to FIG. 6A, between each pair of the adjacent units 46 in the substrate 40, a first groove 54 is formed from above and a second groove 56 is formed from below. Both grooves have a V-shaped cross section.

Here, the first and second grooves 54 and 56 may have the same size (depth) or one of them may be formed larger than the other. Alternatively, only one of the first and second grooves 54 and 56 may be provided if no problem arises in a subsequent step.

The first and second grooves 54 and 56 are formed by partially cutting the substrate 40 while rotating a cutting saw having a V-shaped cross section at high speed along the boundary between each pair of the adjacent units 46. In this step, the substrate 40 is not separated into pieces by the cutting, but is maintained in a one-piece state even after the formation of the grooves.

Fifth Step:

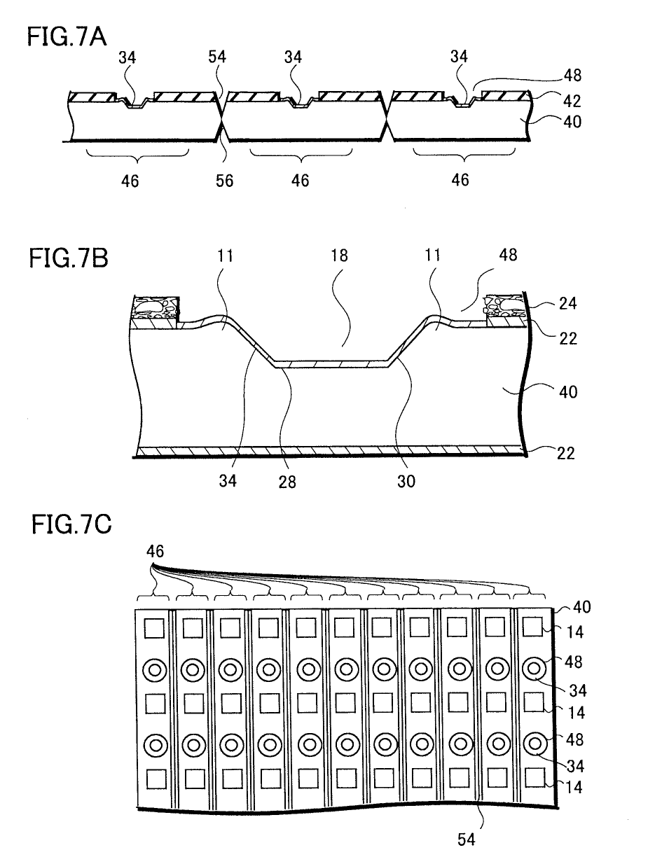

With reference to the drawings in FIG. 7, in this step, the surface of the substrate 40 exposed from each opening 48 is covered with a cover layer 34.

In this step, the substrate 40 made of metal is used as an electrode to perform conduction, thereby forming a cover layer 34, which is a plating film, on the surface of the substrate 40 exposed from each opening 48. As a material of the cover layer 34, gold, silver or the like is used. Moreover, to prevent the plating film from adhering to surfaces of the first and second grooves 54 and 56, the surfaces of these portions should be covered with a resist. Furthermore, since a rear surface of the substrate 40 is covered with the oxide film 22 that is an insulator, the plating film does not adhere thereto.

By covering the concave part 18 with the cover layer 34 in this step, the metal surface made of aluminum, for example, can be prevented from oxidation. Moreover, by covering the bottom surface 28 of the concave part 18 with the cover layer 34, the light emitting element can be easily mounted using solder in a subsequent step if the cover layer 34 is made of silver or the like with excellent solder wettability. Furthermore, by covering the side surface 30 of the concave part 18 with the cover layer 34 made of a material having high reflectance, the function of the side surface 30 as a reflector can be enhanced.

Sixth Step:

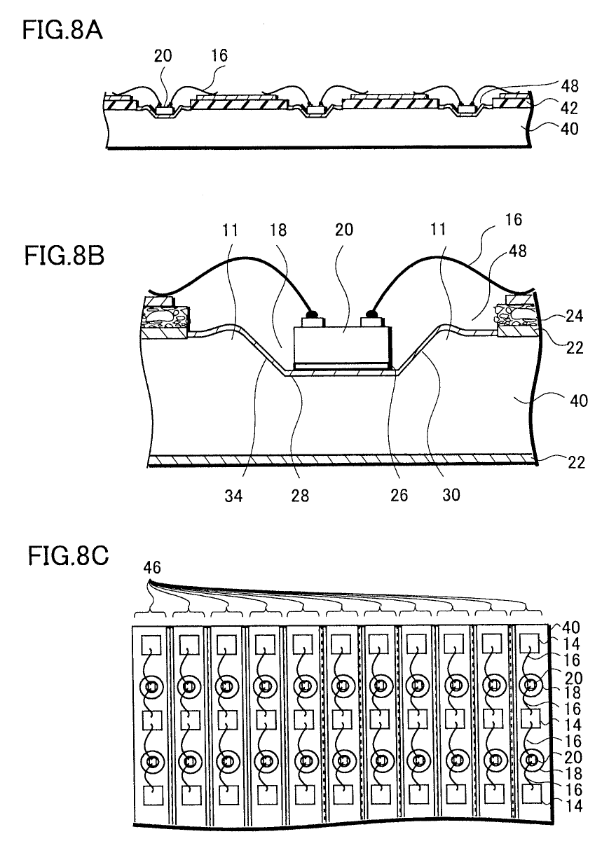

With reference to the drawings in FIG. 8, next, light emitting elements 20 (LED chips) are mounted in the concave parts 18 in each unit 46 and electrically connected to each other. With reference to FIG. 8B, a lower surface of the light emitting element 20 is disposed on the bottom surface 28 of the concave part 18 with a bonding material 26 interposed therebetween. Since the light emitting element 20 has no electrode on the lower surface thereof, both insulating resin adhesive and conductive resin adhesive can be adopted as the bonding material 26. In addition, as the conductive adhesive, both solder and conductive paste can be adopted. Furthermore, since the bottom surface 28 of the concave part 18 is covered with the cover layer 34 that is the plating film such as silver with excellent solder wettability, solder superior in heat conduction to the insulating material can be adopted as the bonding material 26.

After fixing of the light emitting elements 20 is completed, the electrodes provided on the upper surfaces of the light emitting elements 20 and the conductive pattern 14 are connected to each other through thin metal wires 16.

Seventh Step:

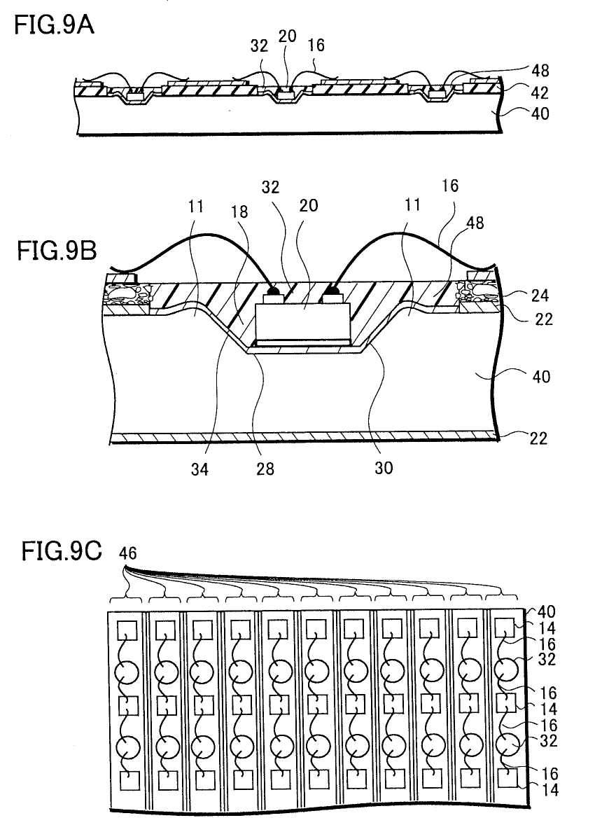

With reference to the drawings in FIG. 9, next, sealing resin 32 is filled in the concave parts 18 in each unit 46 provided to the substrate 40 to thereby seal the light emitting elements 20. The sealing resin 32 is a silicone resin mixed with a fluorescent material, and is filled in a liquid or semisolid state in the concave parts 18 and the openings 48. In this way, the side surfaces and upper surface of each light emitting element 20 and the connecting portions between the light emitting element 20 and the thin metal wires 16 are covered with the sealing resin 32.

In this step, the sealing resin 32 adheres to the convex parts 11 obtained by causing the upper surface of the substrate 40 in the peripheral portions of the concave parts 18 to protrude upward. Thus, adhesion strength between the substrate 40 and the sealing resin 32 is improved.

Furthermore, each of the side surfaces of the insulating layer 24 facing the openings 48 is a rough surface on which the filler extensively filled in the insulating layer 24 is exposed. Therefore, contact between the sealing resin 32 and the filler exposed from the side surfaces of the insulating layer 24 also improves adhesion strength between the sealing resin 32 and the other members.

By individually supplying the sealing resin 32 into each of the concave parts 18 for sealing, a variation in the amount of fluorescent material contained in the sealing resin 32 is suppressed compared with the case where the sealing resin 32 is formed on the entire upper surface of the substrate 40. Thus, the color of light emitted from the light emitting module is uniform.

Eighth Step:

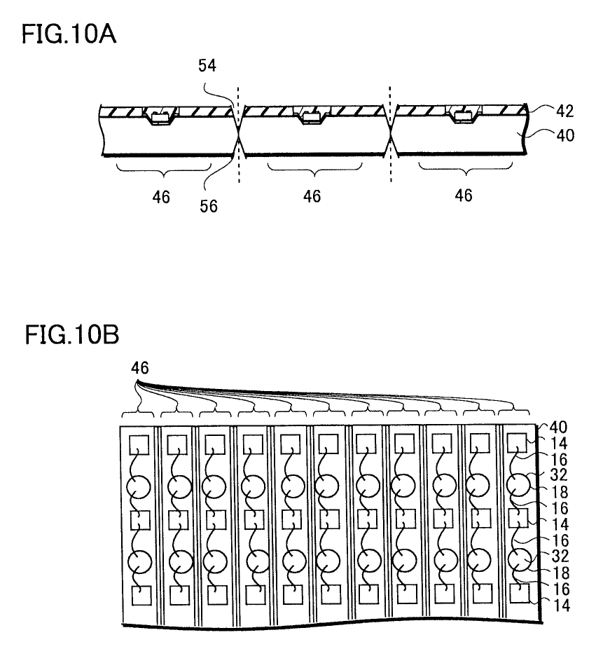

With reference to the drawings in FIG. 10, next, the substrate 40 is divided into the units at the spots where the first and second grooves 54 and 56 are formed.

The both grooves formed between each pair of the adjacent units 46 facilitate division of the substrate 40. As a method for the division, punching by pressing, dicing, bending of the substrate 40 at the spots where the both grooves are formed, or the like can be adopted.

By the above steps, the light emitting module having the configuration shown in FIG. 1 is manufactured.

The order of the above steps can also be rearranged. For example, the step of forming the first grooves 54 and the like shown in FIG. 6 may be performed after the step of forming the sealing resin 32 shown in FIG. 9. Furthermore, the first grooves 54 and the like may be formed immediately after the patterning of the conductive patterns 14 shown in FIG. 2 and then the substrate 40 may be divided into the individual units 46.

The present invention is not limited to the above embodiment, but may have any of the following configurations:
a light emitting module in which one or more light emitting elements 20 are accommodated in each concave part 18.
a light emitting module in which the light emitting elements 20 are blue light emitting elements or ultraviolet light emitting elements and which emits white light by containing a fluorescent material in the sealing resin 32.
a light emitting module in which the light emitting elements 20 are red, green and blue light emitting elements and the sealing resin 32 is transparent or contains diffusing agent.
a light emitting module in which an inner circumferential surface of each concave part 18 is mirror-finished or plated.

### EXPLANATION OF REFERENCE NUMERALS

10 light emitting module
11 convex part
12 metal substrate
14 conductive pattern
16 thin metal wire
18 concave part
20 light emitting element
22 oxide film
24 insulating layer
26 insulating layer
28 bonding material
30 side surface
32 sealing resin
34 cover layer
36 first inclined portion
38 second inclined portion
40 substrate
42 insulating layer
44 conductive foil
46 unit
48 opening
50 mold
51 contact portion
52 convex portion
53 concave portion
54 first groove
56 second groove

1. A light emitting module comprising:
a metal substrate having a first principal surface and a second principal surface and made of a metal;
an insulating layer covering the first principal surface of the metal substrate;
a conductive pattern formed on a surface of the insulating layer;
an opening provided by partially removing the insulating layer;
a concave part provided by denting the metal substrate exposed from the opening; and
a light emitting element accommodated in the concave part and electrically connected to the conductive pattern.

2. The light emitting module according to claim 1, wherein
the concave part has a bottom surface and a side surface connecting the bottom surface and the first principal surface of the metal substrate, and
the side surface is an inclined surface formed such that a width of the concave part gradually increases toward the first principal surface of the metal substrate.

3. The light emitting module according to claim 1, wherein the side surface of the concave part is covered with a cover layer made of a material having higher reflectance of light than that of the metal substrate.

4. The light emitting module according to claim 1, further comprising a sealing resin filled in the concave part and covering the light emitting element.

5. The light emitting module according to claim 1, wherein a filler contained in the insulating layer is exposed on a side surface of the insulating layer facing the opening.

6. The light emitting module according to claim 1, wherein
the metal substrate is a substrate which has the principal surfaces covered with an oxide film and which is made of aluminum, and
the oxide film is removed in a region inside the opening on the first principal surface of the metal substrate.

7. The light emitting module according to claim 1, wherein the concave part is formed deeper than a thickness of the light emitting element.

8. A method for manufacturing a light emitting module, comprising the steps of:
forming a conductive pattern on a surface of an insulating layer covering a first principal surface of a metal substrate;
providing an opening by partially removing the insulating layer, so that the first principal surface of the metal substrate is partially exposed from the opening;
forming a concave part by denting the metal substrate exposed from the opening;
accommodating a light emitting element in the concave part; and
electrically connecting the light emitting element to the conductive pattern.

9. The method for manufacturing a light emitting module, according to claim 8, wherein, in the step of forming the concave part, the concave part is provided by pressing the metal substrate from the first principal surface.

10. The method for manufacturing a light emitting module, according to claim 8, further comprising the step of covering an inner wall of the concave part with a cover layer made of a metal having higher reflectance than that of a material of the metal substrate.

11. The method for manufacturing a light emitting module, according to claim 10, wherein, in the step of covering the inner wall of the concave part, the cover layer is formed by electrolytic plating using the metal substrate as an electrode.

12. A light emitting module comprising:
a substrate having a first principal surface and a second principal surface;
a conductive pattern formed on the first principal surface of the substrate;
a concave part provided by denting the substrate from the first principal surface;
a light emitting element accommodated in the concave part and electrically connected to the conductive pattern;
a convex part formed by raising the first principal surface of the substrate in a region thereof surrounding the concave part; and
a sealing resin filled in the concave part so as to cover the light emitting element and adhering to the convex part.

13. The light emitting module according to claim 12, wherein
the substrate is a metal substrate having its upper surface covered with an insulating layer,
the concave part is formed by denting the metal substrate exposed from an inside of an opening provided by partially removing the insulating layer, and
the convex part is provided by raising the first principal surface of the metal substrate in a region thereof exposed from the inside of the opening and surrounding the concave part.

14. The light emitting module according to claim 13, wherein
the insulating layer is made of a resin mixed with a filler, and
the sealing resin filled in the concave part and the opening adheres to the filler exposed from a side surface of the insulating layer facing the opening.

15. A method for manufacturing a light emitting module, comprising the steps of:
forming a conductive pattern on a first principal surface of a substrate;
pressing the substrate so that the substrate is dent from the first principal surface and thus a concave part is provided and so that the first principal surface of the substrate is raised in a region thereof surrounding the concave part and thus a convex part is provided;
accommodating a light emitting element in the concave part and electrically connecting the light emitting element to the conductive pattern; and
forming a sealing resin so that the sealing resin is filled in the concave part so as to cover the light emitting element and adheres to the convex part.

16. The method for manufacturing a light emitting module, according to claim 15, wherein,
in the step of forming the conductive pattern, the conductive pattern is formed on an upper surface of an insulating layer covering the substrate made of a metal, and
in the step of providing the concave part and the convex part, the concave part and the convex part are provided in the first principal surface of the substrate exposed from an opening provided by partially removing the insulating layer.

17. The method for manufacturing a light emitting module, according to claim 16, wherein, in the step of forming the sealing resin, the sealing resin is brought into contact with a filler exposed from a side surface of the insulating layer facing the opening.

18. The method for manufacturing a light emitting module, according to claim 15, wherein, in the step of providing the concave part and the convex part, the first principal surface of the substrate is pressed with a mold having a shape corresponding to the concave part and the convex part.
